(19) United States
(12) Patent Application Publication
(10) Pub. No.: US 2024/0429886 A1
(43) Pub. Date: Dec. 26, 2024

(54) PUSH-PULL RF POWER AMPLIFIER CIRCUIT AND PUSH-PULL RF POWER AMPLIFIER

(71) Applicant: RADROCK (SHENZHEN) TECHNOLOGY CO., LTD., Shenzhen, Guangdong (CN)

(72) Inventors: Yuan Cao, Shenzhen, Guangdong (CN); Yongjian Lei, Shenzhen, Guangdong (CN); Jianxing Ni, Shenzhen, Guangdong (CN)

(21) Appl. No.: 18/687,817

(22) PCT Filed: Nov. 9, 2022
(86) PCT No.: PCT/CN2022/130748

§ 371 Date: Feb. 29, 2024

(30) Foreign Application Priority Data
Sep. 30, 2021 (CN) 202111159843.2

(51) Int. Cl. H03F 3/26; H03F 3/45

(52) U.S. Cl. CPC H03F 3/265; H03F 3/45484; H03F 2200/09; H03F 2200/451

(57) ABSTRACT

Discloses is a push-pull RF power amplifier circuit, comprising a first differential amplifier transistor, a second differential amplifier transistor, a first balun and a capacitor network. In this application, the primary coil of first balun is improved into a structure in which the first and second coil segment are connected with each other, and the capacitor network is connected at the joint of the first and second coil segment. The capacitor network and first balun jointly participate in impedance matching of the push-pull RF power amplifier circuit, so that the push-pull power amplifier system can support larger bandwidth while achieving impedance matching. There is no need to separately connect capacitors between the output end of the first differential amplifier transistor and the first input end of the first balun, or between the output end of the second differential amplifier transistor and the second input end of the first balun.

This application claims the benefit of Chinese Patent Application No. 202111159843.2,filed on Sep. 30, 2021, entitled “Push-pull power amplifier circuit, push-pull power amplifier and RF front-end module”.

### TECHNICAL FIELD

The application relates to the technical field of radio frequency (RF), in particular to a push-pull RF power amplifier circuit, a push-pull RF power amplifier and an RF front-end module.

### BACKGROUND

The key performance goal of the fifth generation mobile communication technology (5G) is to greatly improve the transmission rate compared with 4G. The new technology of 5G is required to adopt an RF front-end with higher frequency, wider bandwidth and higher-order QAM modulation, which puts forward more stringent requirements for the design of the power amplifier of RF front-end. Push-pull power amplifier is widely used because it can meet the requirements of higher frequency, wider bandwidth and higher-order QAM modulation in a RF front-end. However, in the design of push-pull power amplifier, in order to achieve performance indexes such as impedance matching, it tends to use more impedance matching elements or design more complex circuit structures. As a result, the circuit structure of push-pull power amplifier is complex and the occupied area is too large, which is not conducive to the miniaturization design of push-pull power amplifier.

### SUMMARY

The embodiments of the application provide a push-pull RF power amplifier circuit, a push-pull RF power amplifier and an RF front-end module, aiming at solving the problem that it is difficult to give consideration to both the occupied area and performance for push-pull power amplifier circuit.

A push-pull RF power amplifier circuit, includes a first differential amplifier transistor, a second differential amplifier transistor, a first balun and a capacitor network;

a primary coil of the first balun includes a first coil segment and a second coil segment;

a first end of the capacitor network is connected with a second end of the first coil segment, and a second end of the capacitor network is connected with a first end of the second coil segment;

an output end of the first differential amplifier transistor is coupled to a first end of the first coil segment, and an output end of the second differential amplifier transistor is coupled to a second end of the second coil segment.

Further, the capacitor network includes a first capacitor, a first end of the first capacitor is connected with the second end of the first coil segment, and a second end of the first capacitor is connected with the first end of the second coil segment.

Further, the capacitor network includes a first capacitor and a second capacitor connected in series, a first end of the first capacitor is connected with the second end of the first coil segment, a second end of the first capacitor is connected with a first end of the second capacitor, and a second end of the second capacitor is connected with the first end of the second coil segment.

Further, the second end of the first capacitor is connected to ground.

Further, the push-pull RF power amplifier circuit includes a common-mode rejection circuit, one end of the common-mode rejection circuit is coupled between the first capacitor and the second capacitor, and another end is grounded.

Further, the common-mode rejection circuit includes a first resistor.

Further, the common-mode rejection circuit includes a third capacitor and a first inductor connected in series.

Further, the push-pull RF power amplifier circuit includes a feed power end and a decoupling capacitor, wherein the output end of the first differential amplifier transistor is connected to the feed power end via a second inductor, and the output end of the second differential amplifier transistor is connected to the feed power end via a third inductor; one end of the decoupling capacitor is connected to the feed power end, and another end is grounded.

Further, the capacitor network has a capacitance value smaller than that of a DC blocking capacitor connected in series between the output end of the first differential amplifier transistor and a first end of the primary coil in a comparable push-pull RF power amplifier circuit; and/or, the capacitor network has a capacitance value smaller than that of a DC blocking capacitor connected in series between the output end of the second differential amplifier transistor and a second end of the primary coil in a comparable push-pull RF power amplifier circuit.

Further, the capacitance value of the capacitor network is half of that of a DC blocking capacitor connected in series between the output end of the first differential amplifier transistor and a first end of the primary coil in a comparable push-pull RF power amplifier circuit; and/or, the capacitance value of the capacitor network is half of that of a DC blocking capacitor connected in series between the output end of the second differential amplifier transistor and a second end of the primary coil in a comparable push-pull RF power amplifier circuit.

Further, the first differential amplifier transistor is a BJT and has a base, a collector and an emitter, wherein the base of the first differential amplifier transistor receives a first RF input signal, the collector of the first differential amplifier transistor is coupled to the first end of the first coil segment, and the emitter of the first differential amplifier transistor is grounded; the second differential amplifier transistor is a BJT and has a base, a collector and an emitter, wherein the base of the second differential amplifier transistor receives a second RF input signal, the collector of the second differential amplifier transistor is coupled to the second end of the second coil segment, and the emitter of the second differential amplifier transistor is grounded.

Further, a first end of a secondary coil of the first balun outputs an amplified first RF output signal, and a second end of a secondary coil outputs an amplified second RF output signal; or, the first end of the secondary coil of the first balun outputs an amplified RF output signal, and the second end of the secondary coil is grounded.

Further, the push-pull RF power amplifier circuit includes a first feed power end and a second feed power end, wherein the first feed power end is connected to the first end of the first coil segment, and the second feed power end is connected to the second end of the second coil segment.

A push-pull RF power amplifier is provided, including a substrate, a push-pull power amplifier chip arranged on the substrate and a first balun arranged on the substrate;

the push-pull power amplifier chip includes a first differential amplifier transistor, a second differential amplifier transistor and a capacitor network;

a primary coil of the first balun includes a first coil segment and a second coil segment;

a first end of the capacitor network is connected with a second end of the first coil segment, and a second end of the capacitor network is connected with a first end of the second coil segment;

an output end of the first differential amplifier transistor is coupled to a first end of the first coil segment, and an output end of the second differential amplifier transistor is coupled to a second end of the second coil segment.

Further, the first end of the capacitor network is connected to a first pad of the push-pull power amplifier chip, and the first pad is bonded to the second end of the first coil segment by a wire; the second end of the capacitor network is connected to a second pad of the push-pull power amplifier chip, and the second pad is bonded to the first end of the second coil segment by a wire.

Further, the capacitor network includes a first capacitor, a first end of the first capacitor is connected to the first pad of the push-pull power amplifier chip, and the first pad is bonded to the second end of the first coil segment by a wire; a second end of the first capacitor is connected to the second pad of the push-pull power amplifier chip, and the second pad is bonded to the first end of the second coil segment by a wire.

Further, the capacitor network includes a first capacitor and a second capacitor connected in series, the first end of the first capacitor is connected to the first pad of the push-pull power amplifier chip, and the first pad is bonded to the second end of the first coil segment by a wire; the second end of the first capacitor is connected with a first end of the second capacitor, a second end of the second capacitor is connected with the second pad of the push-pull power amplifier chip, and the second pad is bonded to the first end of the second coil segment by a wire.

Further, the second end of the first capacitor is connected to ground; or the second end of the first capacitor is connected to ground through a common-mode rejection circuit.

Further, the output end of the first differential amplifier transistor is connected to a third pad of the push-pull power amplifier chip, and the third pad is bonded to the first end of the first coil segment by a wire; the output end of the second differential amplifier transistor is connected to a fourth pad of the push-pull power amplifier chip, and the fourth pad is bonded to the second end of the second coil segment by a wire.

A push-pull RF power amplifier is provided, including a substrate, a push-pull power amplifier chip arranged on the substrate, and a first balun and a capacitor network arranged on the substrate; the push-pull power amplifier chip includes a first differential amplifier transistor and a second differential amplifier transistor; a primary coil of the first balun includes a first coil segment and a second coil segment; a first end of the capacitor network is connected with a second end of the first coil segment, and a second end of the capacitor network is connected with a first end of the second coil segment; an output end of the first differential amplifier transistor is coupled to a first end of the first coil segment, and an output end of the second differential amplifier transistor is coupled to a second end of the second coil segment.

Further, the capacitor network includes a first capacitor, a first end of the first capacitor is connected with the second end of the first coil segment, and a second end of the first capacitor is connected with the first end of the second coil segment.

Further, the push-pull RF power amplifier includes a fourth capacitor, and the fourth capacitor and the first capacitor are connected in parallel.

Further, the capacitor network includes a first capacitor and a second capacitor connected in series, a first end of the first capacitor is connected with the second end of the first coil segment, a second end of the first capacitor is connected with a first end of the second capacitor, and a second end of the second capacitor is connected with the first end of the second coil segment.

Further, the push-pull RF power amplifier includes a fourth capacitor; the fourth capacitor is connected in parallel with the first capacitor, or the fourth capacitor is connected in parallel with the second capacitor.

Further, the first capacitor, the second capacitor and the fourth capacitor are all SMD capacitors.

Further, the push-pull RF power amplifier circuit includes a common-mode rejection circuit, one end of the common-mode rejection circuit is coupled between the first capacitor and the second capacitor, and another end is grounded.

An RF front-end module is further provided, including a push-pull RF power amplifier circuit described above, or a push-pull RF power amplifier described above.

The above-mentioned push-pull RF power amplifier circuit includes a first differential amplifier transistor, a second differential amplifier transistor, a first balun and a capacitor network; a primary coil of the first balun includes a first coil segment and a second coil segment; a first end of the capacitor network is connected with a second end of the first coil segment, and a second end of the capacitor network is connected with a first end of the second coil segment; an output end of the first differential amplifier transistor is coupled to a first end of the first coil segment, and an output end of the second differential amplifier transistor is coupled to a second end of the second coil segment. In this application, the primary coil of first balun is improved into a structure in which the first coil segment and the second coil segment are connected with each other, and the capacitor network is connected at the joint of the first coil segment and the second coil segment. The capacitor network and first balun jointly participate in impedance matching of the push-pull RF power amplifier circuit to improve the bandwidth performance of the push-pull power amplifier circuit, especially the bandwidth performance of the fundamental wave impedance. Moreover, the occupied area of the push-pull RF power amplifier circuit is further reduced while ensuring the overall performance of the push-pull RF power amplifier circuit.

The above-mentioned push-pull RF power amplifier includes a substrate, a push-pull power amplifier chip arranged on the substrate and a first balun arranged on the substrate; the push-pull power amplifier chip includes a first differential amplifier transistor, a second differential amplifier transistor and a capacitor network; a primary coil of the first balun includes a first coil segment and a second coil segment; a first end of the capacitor network is connected with a second end of the first coil segment, and a second end of the capacitor network is connected with a first end of the second coil segment;

an output end of the first differential amplifier transistor is coupled to a first end of the first coil segment, and an output end of the second differential amplifier transistor is coupled to a second end of the second coil segment. In the application, the capacitor network arranged on the push-pull power amplifier chip is connected to the connection of the first coil segment and the second coil segment of the first balun arranged on the substrate. The capacitor network and first balun jointly participate in impedance matching of the push-pull RF power amplifier circuit to improve the bandwidth performance of the push-pull power amplifier circuit, especially the bandwidth performance of the fundamental wave impedance. Moreover, since the capacitor network is arranged on the push-pull power amplifier chip, the occupied area of the push-pull RF power amplifier can be reduced, and meanwhile, the quality factor can be improved, thus optimizing the overall performance of the push-pull RF power amplifier circuit.

The above-mentioned push-pull RF power amplifier includes a substrate, a push-pull power amplifier chip arranged on the substrate, and a first balun and a capacitor network arranged on the substrate; the push-pull power amplifier chip includes a first differential amplifier transistor and a second differential amplifier transistor; a primary coil of the first balun includes a first coil segment and a second coil segment; a first end of the capacitor network is connected with a second end of the first coil segment, and a second end of the capacitor network is connected with a first end of the second coil segment; an output end of the first differential amplifier transistor is coupled to a first end of the first coil segment, and an output end of the second differential amplifier transistor is coupled to a second end of the second coil segment. In the application, the capacitor network is directly connected between the first coil section and the second coil section of the primary coil, there is no need to set an extra pad on the push-pull power amplifier chip or connect the capacitor network back to the push-pull power amplifier chip by wires. In this way, the problem of parasitic inductance caused by wires can be avoided, and the bandwidth performance of the push-pull power amplifier can be optimized.

### BRIEF DESCRIPTION OF THE DRAWINGS

In order to explain the technical solution of the embodiments of this application more clearly, the drawings described in the description of the embodiments of this application will be briefly introduced below. Obviously, the drawings in the present application and their accompanying detailed description are directed to merely exemplary embodiments of the application. For those of ordinary skill in this field, other drawings may be obtained according to these drawings without any creative effort.

FIG. 1 is a schematic circuit diagram of a push-pull RF power amplifier circuit according to an embodiment of the present application.

FIG. 2 is another schematic diagram of a push-pull RF power amplifier circuit according to an embodiment of the present application.

FIG. 3 is another schematic diagram of a push-pull RF power amplifier circuit according to an embodiment of the present application.

FIG. 4 is another schematic diagram of a push-pull RF power amplifier circuit according to an embodiment of the present application.

FIG. 5 is another schematic diagram of a push-pull RF power amplifier circuit according to an embodiment of the present application.

FIG. 6 is another schematic diagram of a push-pull RF power amplifier circuit according to an embodiment of the present application.

FIG. 7 is another schematic diagram of a push-pull RF power amplifier circuit according to an embodiment of the present application.

FIG. 8 is another schematic diagram of a push-pull RF power amplifier circuit according to an embodiment of the present application.

FIG. 9 is another schematic diagram of a push-pull RF power amplifier circuit according to an embodiment of the present application.

FIG. 10 is another schematic diagram of a push-pull RF power amplifier circuit according to an embodiment of the present application.

FIG. 11 is another schematic diagram of a push-pull RF power amplifier circuit according to an embodiment of the present application.

FIG. 12 is a schematic circuit diagram of a push-pull RF power amplifier according to an embodiment of the present application.

FIG. 13 is another schematic circuit diagram of a push-pull RF power amplifier according to an embodiment of the present application.

FIG. 14 is another schematic circuit diagram of a push-pull RF power amplifier according to an embodiment of the present application.

FIG. 15 is another schematic circuit diagram of a push-pull RF power amplifier according to an embodiment of the present application.

FIG. 16 is another schematic circuit diagram of a push-pull RF power amplifier according to an embodiment of the present application.

FIG. 17 is another schematic circuit diagram of a push-pull RF power amplifier according to an embodiment of the present application.

FIG. 18 is another schematic circuit diagram of a push-pull RF power amplifier according to an embodiment of the present application.

FIG. 19 is another schematic circuit diagram of a push-pull RF power amplifier according to an embodiment of the present application.

FIG. 20 is another schematic circuit diagram of a push-pull RF power amplifier according to an embodiment of the present application.

FIG. 21 is another schematic circuit diagram of a push-pull RF power amplifier according to an embodiment of the present application.

### REFERENCE SIGNS IN THE FIGURES ARE AS FOLLOWS

10. First differential amplifier transistor; 20. Second differential amplifier transistor; 30. First balun; 50. Capacitor network; C1. First capacitor; C2. Second capacitor; C2. Third capacitor; C4. Fourth capacitor; L1. First inductor; L2. Second inductor; L3. Third inductor; R1. First resistor; VCC1. First feed power end; VCC2. Second feed power end; 100. Substrate; 200. Push-pull power amplifier chip; a. First pad; b. Second pad; c. Third pad; d. Fourth pad.

### DETAILED DESCRIPTION OF PREFERRED EMBODIMENTS

The technical solutions in the embodiments of the present application will be clearly and completely described below with reference to the drawings in the embodiments of this application. Obviously, the described embodiments are part of the embodiments of this application, but not all of them. Based on the embodiments in this application, all other embodiments obtained by those of ordinary skill in the art without creative effort belong to the protection scope of this application.

It should be understood that the exemplary embodiments may be embodied in many different forms and should not be construed as being limited to the exemplary embodiments set forth herein. Rather, these embodiments are provided so that this disclosure will be thorough and complete, and will fully convey the protection scope of this application to those skilled in the art. In the drawings, like reference signs refer to like elements throughout, and the size and relative sizes of layers and regions may be exaggerated for clarity.

It should be understood that when an element or layer is referred to as being “on”, “adjacent to”, “connected with” or “coupled to” other elements or layers, it may be directly on, adjacent to, connected with or coupled to other elements or layers, or intervening elements or layers. Rather, when an element is referred to as being “directly on”, “directly adjacent to”, “directly connected with” or “directly coupled to” other elements or layers, there is no intervening element or layer. It should be understood that although the terms first, second, third, etc. are used to describe various elements, components, areas, layers and/or parts, these elements, components, areas, layers and/or parts should not be limited by these terms. These terms are only used to distinguish one element, part, area, layer or part from another element, part, area, layer or part. Therefore, without departing from the teachings of this application, the first element, part, area, layer or part discussed below may be represented as the second element, part, area, layer or part.

Spatial terms such as “below”, “under”, “above” and “on” may be used here for convenience of description to describe the relationship between one element or feature and other elements or features shown in the figures. It should be understood that in addition to the orientations shown in the figures, the spatial relationship terms are intended to include different orientations of devices in use and operation. For example, if the device in the figures is turned upside down, then the elements or features described as “below” or “under” other elements or features would be “above” or “on” other elements or features. Therefore, the exemplary terms “below” or “under” may include the orientations of “above” or “on”. The device may be otherwise oriented (rotated by 90 degrees or other orientations) and the spatial description terms used here are interpreted accordingly.

The terms used here are only for the purpose of describing specific embodiments and not as a limitation of the present application. As used herein, singular forms of “a”, “an” and “the/said” are also intended to include plural forms, unless the context clearly indicates otherwise. It should also be understood that the terms “comprise” and/or “include” used in this specification specify the presence of said features, integers, steps, operations, elements and/or components, but do not exclude the presence or addition of one or more other features, integers, steps, operations, elements, components and/or groups. As used herein, the term “and/or” includes any and all combinations of related listed items.

For a thorough understanding of this application, detailed structures and steps will be set forth in the following description, so as to illustrate the technical solution proposed in the present application. The preferred embodiments of the present application are described in detail as follows, but besides these detailed descriptions, the present application may also have other embodiments.

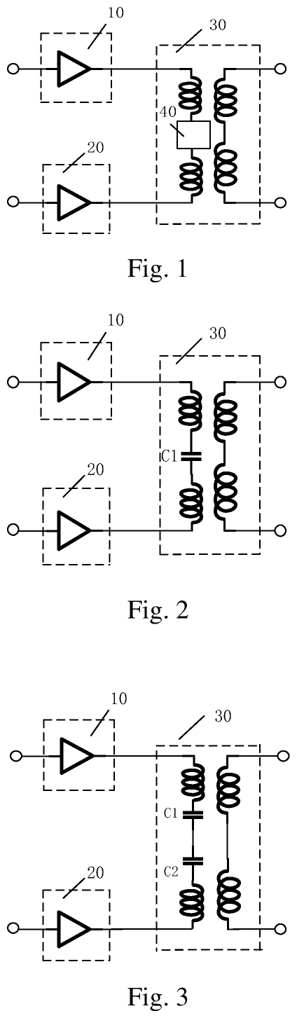

This embodiment provides a push-pull RF power amplifier circuit, as shown in FIG. 1, which includes a first differential amplifier transistor 10, a second differential amplifier transistor 20, a first balun 30 and a capacitor network 40.

The first differential amplifier transistor 10 and the second differential amplifier transistor 20 may be Bipolar junction transistors (BJT) or field effect transistors (FET). Optionally, the first differential amplifier transistor 10 includes at least one BJT (e.g., HBT) or at least one field effect transistor. As an example, the first differential amplifier transistor 10 may be a plurality of BJTs connected in parallel. The second differential amplifier transistor 20 includes at least one BJT (e.g., HBT) or at least one field effect transistor. As an example, the second differential amplifier transistor 20 may be a plurality of BJTs connected in parallel.

In a specific embodiment, the first differential amplifier transistor 10 is configured to amplify a first RF input signal and output a first RF amplified signal (amplified first RF input signal), and the first RF amplified signal is coupled to the first end of the primary coil of the first balun 30 via the first differential amplifier transistor 10. The second differential amplifier transistor 20 is configured to amplify a second RF input signal and output a second RF amplified signal (amplified second RF input signal), and the second RF amplified signal is coupled to the second end of the primary coil of the first balun 30 via the second differential amplifier transistor 20. The first RF input signal may be the RF signal output after amplification by the corresponding pre-stage amplifier circuit. Or, the first RF input signal can also be one of the balanced RF signals obtained by converting unbalanced input RF signals. Similarly, the second RF input signal may be the RF signal output after amplification by the corresponding pre-stage amplifier circuit. Or, the second RF input signal may also be one of the balanced RF signals obtained by converting unbalanced input RF signals.

It can be understood that the first differential amplifier transistor 10 and the second differential amplifier transistor 20 may be any amplifier stage in the push-pull RF power amplifier circuit, and for example, the amplifier stage may be any stage in the driving stage, the intermediate stage or the output stage.

In a specific embodiment, the push-pull RF power amplifier circuit further includes a pre-stage conversion circuit (not shown). For example, the pre-stage conversion circuit may be realized by a pre-stage conversion balun. The pre-stage conversion balun is used to convert the unbalanced RF input signal into a balanced first RF input signal and a balanced second RF input signal, input the first RF input signal to the input end of the first differential amplifier transistor 10, and input the second RF input signal to the input end of the second differential amplifier transistor 20.

The primary coil of the first balun 30 includes a first coil segment and a second coil segment. The first end of the capacitor network 40 is connected with the second end of the first coil segment, and the second end of the capacitor network 40 is connected with the first end of the second coil segment. The output end of the first differential amplifier transistor 10 is coupled to the first end of the first coil segment, and the output end of the second differential amplifier transistor 20 is coupled to the second end of the second coil segment.

In a specific embodiment, the first coil segment and the second coil segment of the primary coil of the first balun 30 may be separately arranged. The first coil segment and the second coil segment are connected via a capacitor network 40, and the capacitor network 40 cooperates with the first balun 30 to participate in impedance matching of the push-pull power amplifier circuit, so as to improve the bandwidth performance of the push-pull power amplifier circuit, especially the bandwidth performance of the fundamental wave impedance.

In another specific embodiment, the first coil segment and the second coil segment of the primary coil of the first balun 30 may also be arranged in a non-separated manner, i.e.., the first coil segment and the second coil segment are still essentially a complete coil. The capacitor network 40 is connected to the primary coil of the first balun 30 to cooperate with the first balun 30 to participate in impedance matching of the push-pull power amplifier to improve the bandwidth performance of push-pull power amplifier circuit, especially the bandwidth performance of fundamental wave impedance.

It should be noted that the specific implementation of the secondary coil of the first balun 30 is not limited in this embodiment. For example, the secondary coil of the first balun 30 may be composed of two separately arranged coil segments or a complete coil.

In this embodiment, the first balun 30 may be arranged on the substrate, or be integrated with the first differential amplifier transistor 10 and the second differential amplifier transistor 20 on the same chip; or it may be arranged separately on an independent chip (e.g., the first differential amplifier transistor 10 and the second differential amplifier transistor 20 are arranged on the first chip, and the first balun 30 is arranged on the second chip). The settings may be customized according to actual needs.

In this embodiment, the push-pull RF power amplifier circuit includes a first differential amplifier transistor, a second differential amplifier transistor, a first balun and a capacitor network; a primary coil of the first balun includes a first coil segment and a second coil segment; a first end of the capacitor network is connected with a second end of the first coil segment, and a second end of the capacitor network is connected with a first end of the second coil segment; an output end of the first differential amplifier transistor is coupled to a first end of the first coil segment, and an output end of the second differential amplifier transistor is coupled to a second end of the second coil segment. In this application, the primary coil of first balun is improved into a structure in which the first coil segment and the second coil segment are connected with each other, and the capacitor network is connected at the joint of the first coil segment and the second coil segment. The capacitor network and first balun jointly participate in impedance matching of the push-pull RF power amplifier circuit to improve the bandwidth performance of the push-pull power amplifier circuit, especially the bandwidth performance of the fundamental wave impedance. Moreover, the occupied area of the push-pull RF power amplifier circuit is further reduced while ensuring the overall performance of the push-pull RF power amplifier circuit.

In a specific embodiment, the capacitor network has a capacitance value smaller than that of a DC blocking capacitor connected in series between the output end of the first differential amplifier transistor and a first end of the primary coil in a comparable push-pull RF power amplifier circuit; and/or, the capacitor network has a capacitance value smaller than that of a DC blocking capacitor connected in series between the output end of the second differential amplifier transistor and a second end of the primary coil in a comparable push-pull RF power amplifier circuit.

The circuit structure of the comparable push-pull RF power amplifier circuit is basically the same as that of the push-pull RF power amplifier circuit of the present application, except that the first end of the capacitor network in the push-pull RF power amplifier circuit of the present application is connected with the second end of the first coil segment, and the second end is connected with the first end of the second coil segment, while the DC blocking capacitor of the comparable push-pull RF power amplifier circuit is connected in series between the output end of the first differential amplifier transistor and the first end of the primary coil, and the DC blocking capacitor is connected in series between the output end of the second differential amplifier transistor and the second end of the primary coil.

In a specific embodiment, the connection position of the capacitor network 40 of the push-pull RF power amplifier circuit in this embodiment is different from that of the DC blocking capacitors C21/C22 (not shown) in the comparable push-pull RF power amplifier circuit. Therefore, under the same circuit requirements, the capacitance value of the capacitor network 40 of the push-pull RF power amplifier circuit in this embodiment is smaller than that of the first DC blocking capacitor connected in series between the output end of the first differential amplifier transistor and the first end of the primary coil in the comparable push-pull RF power amplifier circuit; and/or, the capacitance value of the capacitor network 40 is smaller than that of the second DC blocking capacitor connected in series between the output end of the second differential amplifier transistor and the second end of the primary coil in the comparable push-pull RF power amplifier circuit.

In this embodiment, the primary coil of the first balun 30 is improved into a structure in which the first coil segment and the second coil segment are connected with each other, and the capacitor network 40 is connected at the joint of the first coil segment and the second coil segment. there is no need to connect the first DC blocking capacitor between the output end of the first differential amplifier transistor 10 and the first input end of the first balun 30, or connect the second DC blocking capacitor between the output end of the second differential amplifier transistor 20 and the second input end of the first balun 30. That is, by connecting the capacitor network 40 to the connection position between the first coil segment and the second coil segment of the primary coil of the first balun 30, the functions of the first DC blocking capacitor and second DC blocking capacitor can be realized at the same time, and the capacitance value of the capacitor network 40 is smaller than that of the first DC blocking capacitor and/or the second DC blocking capacitor. Thus, while improving the bandwidth performance of the push-pull power amplifier circuit, especially the bandwidth performance of the fundamental wave impedance, the occupied area of the push-pull RF power amplifier circuit is further reduced.

In a specific embodiment, the capacitance value of the capacitor network 40 is half of that of a DC blocking capacitor connected in series between the output end of the first differential amplifier transistor and a first end of the primary coil in a comparable push-pull RF power amplifier circuit; and/or, the capacitance value of the capacitor network 40 is half of that of a DC blocking capacitor connected in series between the output end of the second differential amplifier transistor and a second end of the primary coil in a comparable push-pull RF power amplifier circuit.

Furthermore, the connection position of the capacitor network 40 is different. Therefore, under the same circuit requirements, the capacitance value of the capacitor network 40 is only half of the capacitance value of the DC blocking capacitor connected in series between the output end of the first differential amplifier transistor and the first end of the primary coil in the comparable push-pull RF power amplifier circuit; and/or, the capacitance value of the capacitor network 40 is half of that of the DC blocking capacitor connected in series between the output end of the second differential amplifier transistor and the second end of the primary coil in the comparable push-pull RF power amplifier circuit. Thus, the space occupied by the improved capacitor network 40 is only a quarter of that of the two DC blocking capacitors, which is helpful to further reduce the occupied area of the push-pull RF power amplifier circuit.

In a specific embodiment, referring to FIG. 2 below, the capacitor network 40 includes a first capacitor C1, a first end of the first capacitor C1 is connected with the second end of the first coil segment, and a second end of the first capacitor C1 is connected with the first end of the second coil segment.

In this embodiment, the primary coil of first balun is improved into a structure in which the first coil segment and the second coil segment are connected with each other, and the first capacitor C1 is connected at the joint of the first coil segment and the second coil segment. The first capacitor C1 and the first balun jointly participate in impedance matching of the push-pull RF power amplifier circuit, so as to improve the bandwidth performance of the push-pull power amplifier circuit, especially the bandwidth performance of the fundamental wave impedance. Moreover, the occupied area of the push-pull RF power amplifier circuit is further reduced while ensuring the overall performance of the push-pull RF power amplifier circuit.

In a specific embodiment, as shown in FIG. 3 below, the capacitor network 40 includes a first capacitor C1 and a second capacitor C2 connected in series, a first end of the first capacitor C1 is connected with the second end of the first coil segment, a second end of the first capacitor C1 is connected with a first end of the second capacitor C2, and a second end of the second capacitor C2 is connected with the first end of the second coil segment.

In this embodiment, the primary coil of first balun is improved into a structure in which the first coil segment and the second coil segment are connected with each other, and the first capacitor C1 and the second capacitor C2 are connected at the joint of the first coil segment and the second coil segment. The first capacitor C1 and the second capacitor C2 participate in impedance matching of the push-pull RF power amplifier circuit together with the first balun, so as to improve the bandwidth performance of the push-pull RF power amplifier circuit, especially the bandwidth performance of the fundamental wave impedance.

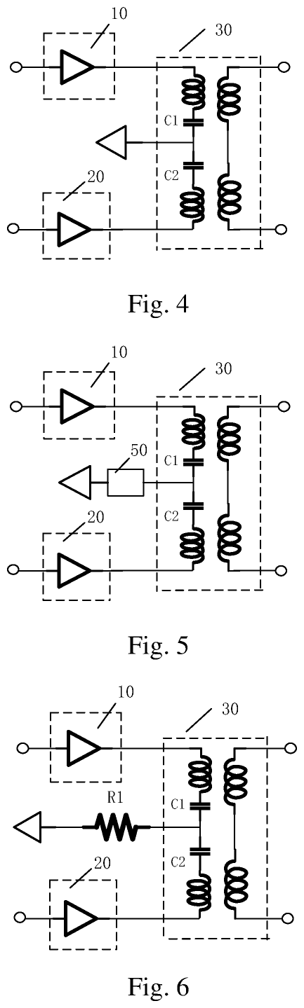

In a specific embodiment, as shown in FIG. 4 below, the second end of the first capacitor C1 is connected to ground.

In this embodiment, the primary coil of first balun is improved into a structure in which the first coil segment and the second coil segment are connected with each other, and the first capacitor C1 and the second capacitor C2 are connected at the joint of the first coil segment and the second coil segment. The first capacitor C1 and the second capacitor C2 participate in impedance matching of the push-pull RF power amplifier circuit together with the first balun, and the common-mode rejection point formed between the first capacitor C1 and the second capacitor C2 is connected to ground, i.e.., the second end of the first capacitor C1 is connected to ground, which is beneficial to improving the common-mode rejection ratio of the push-pull RF power amplifier circuit.

In a specific embodiment, as shown in FIG. 5 below, it further includes a common-mode rejection circuit 50, one end of which is coupled between the first capacitor and the second capacitor, and the other end is grounded.

In a specific embodiment, referring to FIG. 6 below, the common-mode rejection circuit 50 includes a first resistor R1.

In a specific embodiment, the common-mode rejection circuit 50 is connected between the connection node of the first capacitor C1 and second capacitor C2 and ground, and the common-mode rejection circuit 50 works together with the first capacitor C1 and second capacitor C2, so that the common-mode rejection ratio of the push-pull RF power amplifier circuit can be further improved. The common-mode rejection circuit 50 may be a circuit structure consisting of resistors, capacitors or inductors connected in series or parallel.

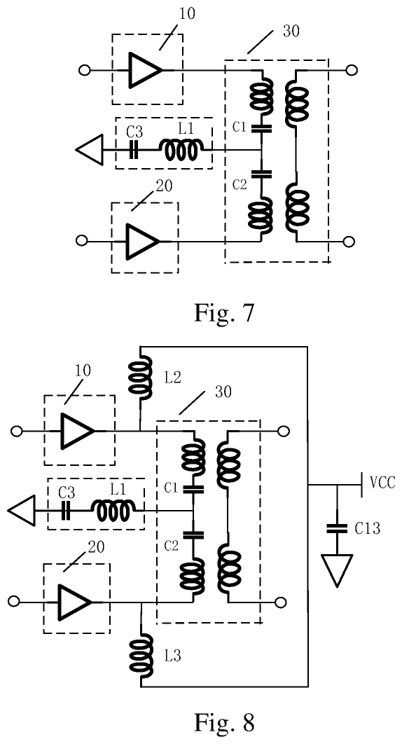

In a specific embodiment, as shown in FIG. 7 below, the common-mode rejection circuit includes a third capacitor C3 and a first inductor L1 connected in series. And, the frequency points of the third capacitor C3 and the first inductor L1 can be resonated at the resonance frequency point of a certain order harmonic (e.g., the second harmonic), so that the common-mode rejection ratio of the push-pull RF power amplifier circuit can be improved, and the harmonic rejection capability of the push-pull RF power amplifier circuit can also be improved.

In a specific embodiment, as shown in FIG. 8 below, it further includes a feed power end VCC and a decoupling capacitor C13, and the output end of the first differential amplifier transistor 10 is connected to the feed power end VCC via a second inductor L2, and the output end of the second differential amplifier transistor is connected to the feed power end VCC via a third inductor L3; one end of the decoupling capacitor C13 is connected to the feed power end VCC, and another end is grounded.

And, the feed power end VCC is a port connected with the feed power supply. The feedback signal provided by the feed power supply is transmitted to the output end of the first differential amplifier transistor 10 and the output end of the second differential amplifier transistor 20 through the feed power end VCC, so as to ensure that the first differential amplifier transistor 10 and the second differential amplifier transistor 20 can work regularly. The output end of the first differential amplifier transistor 10 is connected to a third pad c of the push-pull power amplifier chip 100; the output end of the second differential amplifier transistor 20 is connected to a fourth pad d of the push-pull power amplifier chip 100; so as to feed the first differential amplifier transistor 10 and the second differential amplifier transistor 20.

Further, it also includes a decoupling capacitor C12, one end of which is connected to the feed power end VCC, and the other end is grounded.

Further, in order to further ensure the stability of the feedback signal provided by the feed power end VCC to the first differential amplifier transistor 10 and the second differential amplifier transistor 20, in the application, a decoupling capacitor C12 is adopted, and one end of the decoupling capacitor C12 is connected to the feed power end VCC, and the other end is grounded. In this application, the feedback signal can be provided to the first differential amplifier transistor 10 and the second differential amplifier transistor 20 simply by using a feed power end VCC. Moreover, by connecting the decoupling capacitor C12 to the feed power end VCC, the stability of the feedback signal provided to the first differential amplifier transistor 10 and the second differential amplifier transistor 20 can be ensured simply by using one coupling capacitor C12. Thereby further reducing the occupied area of the RF front-end module while maintaining the overall performance of the RF front-end module.

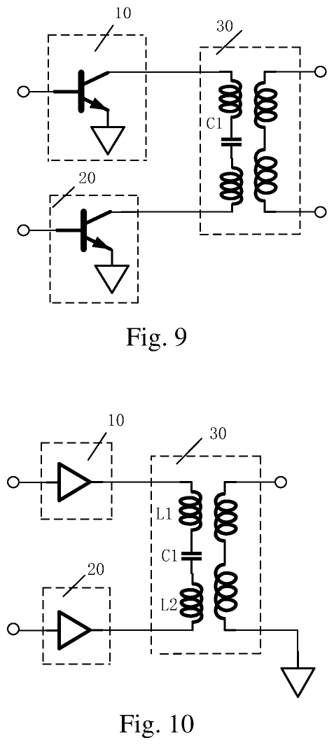

In a specific embodiment, as shown in FIG. 9 below, the first differential amplifier transistor 10 is a BJT and has a base, a collector and an emitter, and the base of the first differential amplifier transistor 10 receives a first RF input signal, the collector of the first differential amplifier transistor 10 is coupled to the first end of the first coil segment, and the emitter of the first differential amplifier transistor 10 is grounded.

Specifically, the first RF input signal is input to the base of the first differential amplifier transistor 10, and after being amplified by the first differential amplifier transistor 10, a first RF amplified signal is output from the collector of the first differential amplifier transistor 10 to the first end of the first coil segment.

The second differential amplifier transistor 10 is a BJT and has a base, a collector and an emitter, and the base of the second differential amplifier transistor 20 receives a second RF input signal, the collector of the second differential amplifier transistor 20 is coupled to the second end of the second coil segment, and the emitter of the second differential amplifier transistor 20 is grounded.

Specifically, the second RF input signal is input to the base of the second differential amplifier transistor 20, and after being amplified by the second differential amplifier transistor 20, a second RF amplified signal is output from the collector of the second differential amplifier transistor 20 to the second end of the second coil segment.

Further, after receiving the first RF amplified signal and the second RF amplified signal, the first balun 30 performs conversion processing on the first RF amplified signal and the second RF amplified signal, and inputs the converted first RF amplified signal and the converted second RF amplified signal to a post-stage circuit.

In a specific embodiment, the first end of the secondary coil of the first balun 30 outputs an amplified first RF output signal, and the second end of the secondary coil outputs an amplified second RF output signal. Alternatively, the first end of the secondary coil of the first balun 30 outputs an amplified RF output signal, and the second end of the secondary coil is grounded.

Referring to FIG. 1 below, the first end of the secondary coil of the first balun 30 outputs the amplified first RF output signal to the post-stage circuit, and the second end of the secondary coil outputs the amplified second RF output signal to the post-stage circuit. Alternatively, the first end of the secondary coil of the first balun 30 outputs the amplified RF output signal, and the second end of the secondary coil is grounded.

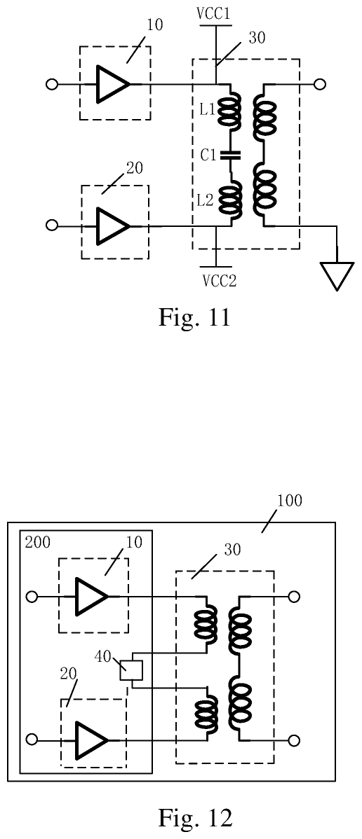

In a specific embodiment, as shown in FIG. 11 below, the push-pull RF power amplifier circuit further includes a first feed power end VCC1 and a second feed power end VCC2, and the first feed power end VCC1 is connected to the first end of the first coil segment, and the second feed power end VCC2 is connected to the second end of the second coil segment.

And, the first feed power end VCC1 is a port connected with a first feed power supply. The feedback signal provided by the first feed power supply is transmitted to the first end of the first coil section through the first feed power end VCC1, so as to ensure that the first differential amplifier transistor 10 can work regularly. The second feed power end VCC2 is the port connected with a second feed power supply. The feedback signal provided by the second feed power supply is transmitted to the second end of the second coil section through the second feed power end VCC2, so as to ensure that the second differential amplifier transistor 20 can work regularly. The first feed power supply and the second feed power supply may be the same feed power supply or different feed power supplies.

In a specific embodiment, the first feed power end VCC1 may be coupled to the first end of the first coil segment via a first feed inductor (not shown); the second feed power end VCC2 may be coupled to the second end of the second coil segment via a second feed inductor (not shown). Alternatively, the first feed power end VCC1 may be coupled to the first end of the first coil segment via a first transmission line (not shown); the second feed power end VCC2 may be coupled to the second end of the second coil segment via a second transmission line (not shown). The DC signal provided by the first feed power end and second feed power end in this embodiment do not need to pass through the coils in the first balun 30, thus there is no DC signal passing through the coil in the first balun 30. Compared with the way that the feed signal provided by the feed power supply is transmitted to the first differential amplifier transistor 10 and the second differential amplifier transistor 20 through the first balun 30, the coil width of the first balun 30 in this embodiment can be designed to be narrower to further reduce the occupied area of the push-pull RF power amplifier circuit.

Referring to FIG. 12 below, the application further provides a push-pull RF power amplifier, including a substrate 100, a push-pull power amplifier chip 200 arranged on the substrate and a first balun 30 arranged on the substrate.

The push-pull power amplifier chip 200 includes a first differential amplifier transistor 10, a second differential amplifier transistor 20 and a capacitor network 40. The primary coil of the first balun 30 includes a first coil segment and a second coil segment. A first end of the capacitor network 40 is connected with a second end of the first coil segment, and a second end of the capacitor network is connected with a first end of the second coil segment; an output end of the first differential amplifier transistor 10 is coupled to a first end of the first coil segment, and an output end of the second differential amplifier transistor 20 is coupled to a second end of the second coil segment.

In this embodiment, the primary coil of the first balun 30 is improved into a structure in which the first coil segment and the second coil segment are connected with each other, and the capacitor network 40 arranged on the push-pull power amplifier chip is connected at the joint of the first coil segment and the second coil segment. There is no need to connect the first DC blocking capacitor between the output end of the first differential amplifier transistor 10 and the first input end of the first balun 30, and no need to connect the second DC blocking capacitor between the output end of the second differential amplifier transistor 20 and the second input end of the first balun 30. That is, by connecting the capacitor network 40 arranged on the push-pull power amplifier chip at the joint of the first coil segment and the second coil segment, not only can the functions of both the first DC blocking capacitor and the second DC blocking capacitor be realized. Moreover, the capacitor network 40 and the first balun 30 jointly participate in impedance matching of the push-pull RF power amplifier circuit, so as to improve the bandwidth performance of the push-pull power amplifier circuit, especially the bandwidth performance of the fundamental wave impedance. In addition, since the capacitor network 40 is arranged on the push-pull power amplifier chip, the occupied area of the push-pull RF power amplifier can be reduced, and meanwhile, the quality factor can be improved, thus optimizing the overall performance of the push-pull RF power amplifier circuit.

Understandably, the connection position of the capacitor network 40 of the push-pull RF power amplifier in this embodiment is different. Therefore, under the same circuit requirements, the capacitance value of the capacitor network 40 is only half of the that of the DC blocking capacitor. Thus, the space occupied by the improved capacitor network 40 is only a quarter of that of two DC blocking capacitors, which is helpful to further reduce the occupied area of the push-pull RF power amplifier

In one embodiment, the first end of the capacitor network 40 is connected to a first pad a of the push-pull power amplifier chip, and the first pad a is bonded to the second end of the first coil segment by a wire; the second end of the capacitor network 40 is connected to a second pad b of the push-pull power amplifier chip, and the second pad b is bonded to the first end of the second coil segment by a wire.

In a specific embodiment, in order to realize the electrical connection between the capacitor network 40 arranged on the push-pull power amplifier chip 200 and the first balun 30 arranged on the substrate, wire bonding may be adopted for the connection. Specifically, in this application, the first pad a and second pad b are provided on the push-pull power amplifier chip 200, the first end of the capacitor network 40 is connected to the first pad a of the push-pull power amplifier chip, and the first pad a is bonded to the second end of the first coil segment by a wire; wherein the first pad a may be bonded to the second end of the first coil segment by one or more wires. The second end of the capacitor network 40 is connected to the second pad b of the push-pull power amplifier chip 200, the second pad b is bonded to the first end of the second coil segment by a wire; wherein, the second pad b may be bonded to the first end of the second coil segment by one or more wires, so that the capacitor network 40 arranged on the push-pull power amplifier chip is connected to the joint of the first coil segment L1 and the second coil segment L2. With the above arrangements, the electrical connection between the capacitor network 40 arranged on the push-pull power amplifier chip 200 and the first coil segment and the second coil segment of the first balun 30 arranged on the substrate is realized.

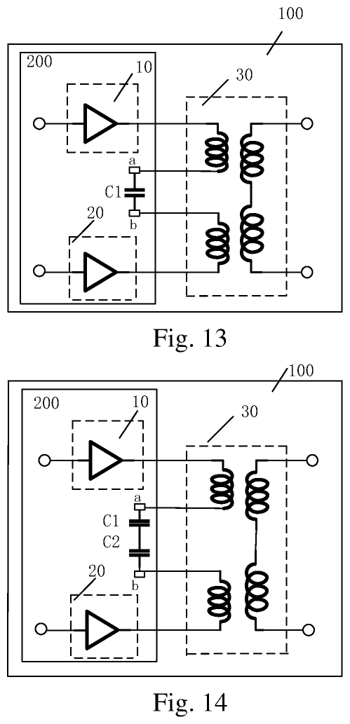

Referring to FIG. 13 below, the capacitor network 40 includes a first capacitor C1, a first end of the first capacitor C1 is connected to the first pad a of the push-pull power amplifier chip, and the first pad a is bonded to the second end of the first coil segment by a wire; a second end of the first capacitor C1 is connected to the second pad of the push-pull power amplifier chip, and the second pad b is bonded to the first end of the second coil segment by a wire.

In this embodiment, the primary coil of first balun is improved into a structure in which the first coil segment and the second coil segment are connected with each other, and the first capacitor C1 is connected at the joint of the first coil segment and the second coil segment. The first capacitor C1 and the first balun jointly participate in impedance matching of the push-pull RF power amplifier circuit to improve the bandwidth performance of the push-pull RF power amplifier circuit, especially the bandwidth performance of the fundamental wave impedance. Moreover, the occupied area of the push-pull RF power amplifier circuit is further reduced while ensuring the overall performance of the push-pull RF power amplifier circuit.

Referring to FIG. 14 below, the capacitor network 40 includes a first capacitor C1 and a second capacitor C2 connected in series, the first end of the first capacitor C1 is connected to the first pad a of the push-pull power amplifier chip, and the first pad a is bonded to the second end of the first coil segment by a wire; the second end of the first capacitor C1 is connected with a first end of the second capacitor C2, a second end of the second capacitor C2 is connected with the second pad b of the push-pull power amplifier chip, and the second pad b is bonded to the first end of the second coil segment by a wire.

In this embodiment, the primary coil of first balun is improved into a structure in which the first coil segment and the second coil segment are connected with each other, and the first capacitor C1 and the second capacitor C2 are connected at the joint of the first coil segment and the second coil segment. The first capacitor C1 and second capacitor C2 participate in impedance matching of the push-pull RF power amplifier circuit together with first balun to improve the bandwidth performance of the push-pull RF power amplifier circuit, especially the bandwidth performance of the fundamental wave impedance. Moreover, a common-mode rejection point is formed between the first capacitor C11 and the second capacitor C2, which is beneficial to improving the common-mode rejection ratio of the push-pull RF power amplifier circuit.

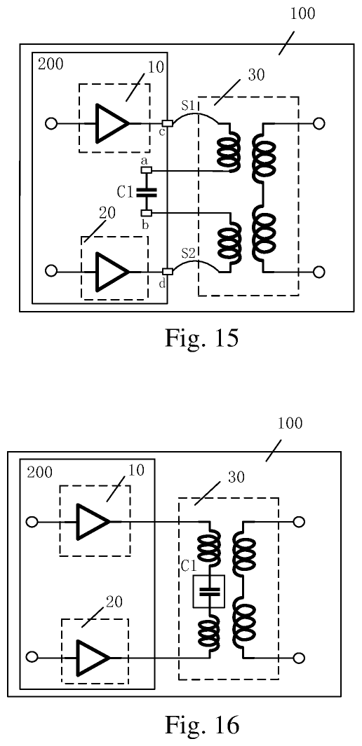

Referring to FIG. 15 below, the output end of the first differential amplifier transistor is connected to a third pad of the push-pull power amplifier chip, and the third pad is bonded to the first end of the first coil segment by a wire; the output end of the second differential amplifier transistor is connected to a fourth pad of the push-pull power amplifier chip, and the fourth pad is bonded to the second end of the second coil segment by a wire.

In a specific embodiment, in order to realize the electrical connection of the first differential amplifier transistor 10 and second differential amplifier transistor 20 arranged on the push-pull power amplifier chip 200 and the first balun 30 arranged on the substrate, wire bonding may be adopted for connection. In this application, the third pad c and fourth pad d are arranged on the push-pull power amplifier chip 200, the output end of the first differential amplifier transistor 10 is connected to the third pad c of the push-pull power amplifier chip 200, and the third pad c is bonded to the first end of the first coil segment by a wire, wherein the third pad c can be bonded to the first end of the first coil segment by one or more wires. The output end of the second differential amplifier transistor 20 is connected to the fourth pad d of the push-pull power amplifier chip 200, and the fourth pad d is bonded to the second end of the second coil segment by a wire, wherein the fourth pad d can be bonded to the second end of the second coil segment by one or more wires. Through the above arrangements, the electrical connection of the first differential amplifier transistor 10 and the second differential amplifier transistor 20 arranged on the push-pull power amplifier chip, and the first balun 30 arranged on the substrate is realized.

Further, the second end of the first capacitor C1 is connected to ground, or the second end of the first capacitor C1 is connected to ground through the common-mode rejection circuit 50. In a specific embodiment, the second end of the first capacitor C1 is connected to ground. Or the second end of the first capacitor C1 is connected to ground through the common-mode rejection circuit 50. The common-mode rejection circuit 50 works together with the first capacitor C1 and the second capacitor C2, so that the common-mode rejection ratio of the push-pull RF power amplifier circuit can be further improved. The common-mode rejection circuit 50 may be a circuit structure consisting of resistors, capacitors or inductors connected in series or parallel.

Referring to FIG. 16 below, the application also provides a push-pull RF power amplifier, including a substrate 100, a push-pull power amplifier chip 200 arranged on the substrate 100, and a first balun 30 and a capacitor network 40 arranged on the substrate 100. The push-pull power amplifier chip 200 includes a first differential amplifier transistor 10 and a second differential amplifier transistor 20. A primary coil of the first balun 30 includes a first coil segment and a second coil segment; a first end of the capacitor network 40 is connected with a second end of the first coil segment, and a second end of the capacitor network 40 is connected with a first end of the second coil segment; an output end of the first differential amplifier transistor 10 is coupled to a first end of the first coil segment, and an output end of the second differential amplifier transistor 20 is coupled to a second end of the second coil segment.

In this embodiment, the primary coil of the first balun 30 is improved into a structure in which the first coil segment and the second coil segment are connected with each other, and the capacitor network 40 is connected at the joint of the first coil segment and the second coil segment. There is no need to connect a capacitor between the output end of the first differential amplifier transistor 10 and the first input end of the first balun 30, and no need to connect a capacitor between the output end of the second differential amplifier transistor 20 and the second input end of the first balun 30. That is, by connecting the capacitor network 40 arranged on the push-pull power amplifier chip at the joint of the first coil segment and the second coil segment, the capacitor network 40 and the first balun 30 jointly participate in impedance matching of the push-pull RF power amplifier, so as to improve the bandwidth performance of the push-pull power amplifier, especially the bandwidth performance of the fundamental wave impedance.

Understandably, the connection position of the capacitor network 40 of the push-pull RF power amplifier in this embodiment is different. Therefore, under the same circuit requirements, the capacitance value of the capacitor network 40 is only half of the that of one DC blocking capacitor. Thus, the space occupied by the improved capacitor network 40 is only a quarter of that of two DC blocking capacitors, which is helpful to further reduce the occupied area of the push-pull RF power amplifier

In this embodiment, the capacitor network 40 is directly connected between the first coil segment and the second coil segment of the primary coil, there is no need to set an extra pad on the push-pull power amplifier chip 200 or connect the capacitor network 40 back to the push-pull power amplifier chip by wires. In this way, the problem of parasitic inductance caused by wires can be avoided, and the bandwidth performance of the push-pull power amplifier can be optimized.

Referring to FIG. 16 below, the capacitor network includes a first capacitor C1, the first end of which is connected with the second end of the first coil segment, and the second end of the first capacitor C1 is connected with the first end of the second coil segment.

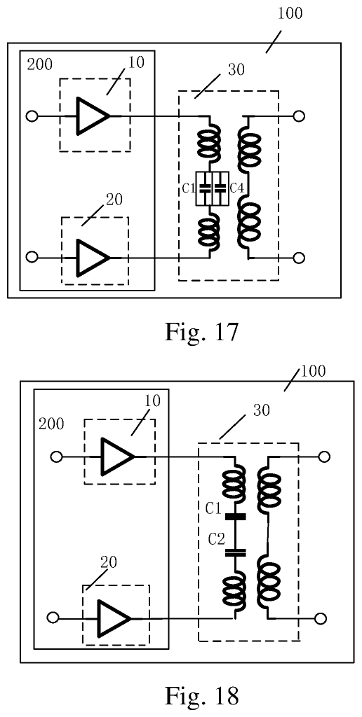

Referring to FIG. 17 below, it further includes a fourth capacitor C4, and the fourth capacitor C4 and the first capacitor C1 are connected in parallel.

In this embodiment, the fourth capacitor C4 and the first capacitor C1 are connected in parallel and then connected between the first coil section and the second coil section of the primary coil. The fourth capacitor C4, the first capacitor C1 and the first balun 30 participate in impedance matching of the push-pull RF power amplifier circuit, so as to improve the bandwidth performance of the push-pull power amplifier circuit, especially the bandwidth performance of the fundamental wave impedance.

It should be noted that this embodiment takes “including a fourth capacitor C4 and a first capacitor C1” as an example, but it does not exclude other specific embodiments that include more capacitors connected in parallel and then connected between the first coil segment and the second coil segment of the primary coil.

Preferably, the fourth capacitor C4 and the first capacitor C1 are SMD capacitors. In this embodiment, the fourth capacitor C4 and the first capacitor C1 arranged on the substrate 100 are packaged in the form of SMD, and are connected in parallel with each other and then connected between the first coil segment and the second coil segment of the primary coil. Compared with the way of arranging the capacitor in the push-pull power amplifier chip, in this application, the fourth capacitor C4 and the first capacitor C1 are packaged in parallel in the form of SMD, and then connected between the first coil segment and the second coil segment of the primary coil. There is no need to set an extra pad on the push-pull power amplifier chip or connect the capacitor network back to the push-pull power amplifier chip by wires. In this way, the problem of parasitic inductance caused by wires can be avoided, and the bandwidth performance of the push-pull power amplifier can be optimized.

Referring to FIG. 18 below, the capacitor network includes a first capacitor C1 and a second capacitor C2 connected in series, a first end of the first capacitor C1 is connected with the second end of the first coil segment, a second end of the first capacitor C1 is connected with a first end of the second capacitor C2, and a second end of the second capacitor C2 is connected with the first end of the second coil segment.

In this embodiment, the primary coil of first balun is improved into a structure in which the first coil segment and the second coil segment are connected with each other, and the first capacitor Cl and the second capacitor C2 are connected at the joint of the first coil segment and the second coil segment. The first capacitor C1 and the second capacitor C2 participate in impedance matching of the push-pull RF power amplifier circuit together with the first balun, so as to improve the bandwidth performance of the push-pull RF power amplifier circuit, especially the bandwidth performance of the fundamental wave impedance.

In a specific embodiment, the connection node of the first capacitor C1 and the second capacitor C2 is connected to ground. In this embodiment, the primary coil of first balun is improved into a structure in which the first coil segment and the second coil segment are connected with each other, and the first capacitor C1 and the second capacitor C2 are connected at the joint of the first coil segment and the second coil segment. The first capacitor C1 and the second capacitor C2 participate in impedance matching of the push-pull RF power amplifier circuit together with the first balun. And the common-mode rejection point formed between the first capacitor C1 and the second capacitor C2 is connected to ground, hence it is beneficial to improving the common-mode rejection ratio of the push-pull RF power amplifier circuit.

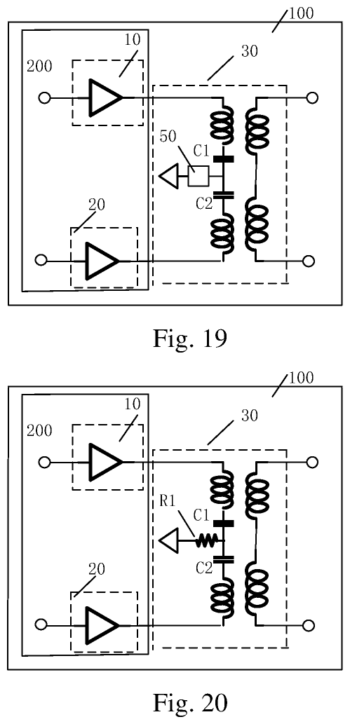

Referring to FIG. 19 below, in a specific embodiment, the push-pull RF power amplifier circuit includes a common-mode rejection circuit 50, one end of the common-mode rejection circuit is coupled between the first capacitor and the second capacitor, and another end is grounded.

Referring to FIG. 20 below, in a specific embodiment, the common-mode rejection circuit 50 further includes a first resistor R1.

Further, in a specific embodiment, the common-mode rejection circuit 50 is connected between the connection node of the first capacitor C1 and second capacitor C2 and the ground, and the common-mode rejection circuit 50 works together with the first capacitor C1 and second capacitor C2, so that the common-mode rejection ratio of the push-pull RF power amplifier circuit can be further improved. The common-mode rejection circuit 50 may be a circuit structure consisting of resistors, capacitors or inductors connected in series or parallel.

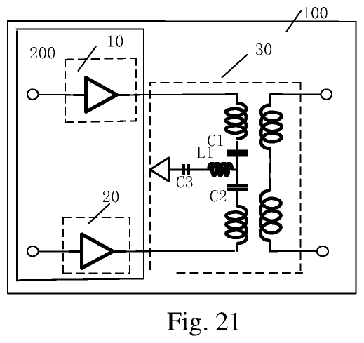

Referring to FIG. 21 below, in a specific embodiment, the common-mode rejection circuit includes a third capacitor C3 and a first inductor L1 connected in series. And, the frequency points of the third capacitor C3 and the first inductor L1 can be resonated at the resonance frequency point of a certain order harmonic (e.g., the second harmonic), so that the common-mode rejection ratio of the push-pull RF power amplifier circuit can be improved, and the harmonic rejection capability of the push-pull RF power amplifier circuit can also be improved.

In a specific embodiment, it further includes a fourth capacitor C4 and a fifth capacitor C5; the fourth capacitor C4 is connected in parallel with the first capacitor C1, and the fifth capacitor C5 is connected in parallel with the second capacitor C2. The first capacitor C1, second capacitor C2, fourth capacitor C4 and fifth capacitor C5 are SMD capacitors.

The embodiment further provides an RF front-end module, which includes the push-pull RF power amplifier circuit described in any of the above embodiments, or includes the push-pull RF power amplifier described in any of the above embodiments.

The RF front-end module includes the push-pull RF power amplifier circuit. The push-pull RF power amplifier circuit includes a first differential amplifier transistor, a second differential amplifier transistor, a first balun and a capacitor network; a primary coil of the first balun includes a first coil segment and a second coil segment; a first end of the capacitor network is connected with a second end of the first coil segment, and a second end of the capacitor network is connected with a first end of the second coil segment; an output end of the first differential amplifier transistor is coupled to a first end of the first coil segment, and an output end of the second differential amplifier transistor is coupled to a second end of the second coil segment. In this application, the primary coil of first balun is improved into a structure in which the first coil segment and the second coil segment are connected with each other, and the capacitor network is connected at the joint of the first coil segment and the second coil segment. The capacitor network and the first balun jointly participate in impedance matching of the push-pull RF power amplifier circuit, so as to improve the bandwidth performance of the push-pull power amplifier circuit, especially the bandwidth performance of the fundamental wave impedance. Moreover, the occupied area of the push-pull RF power amplifier circuit is further reduced while ensuring the overall performance of the push-pull RF power amplifier circuit.

The RF front-end module includes a push-pull RF power amplifier, and the push-pull RF power amplifier includes a substrate, a push-pull power amplifier chip arranged on the substrate and a first balun arranged on the substrate; the push-pull power amplifier chip includes a first differential amplifier transistor, a second differential amplifier transistor and a capacitor network; a primary coil of the first balun includes a first coil segment and a second coil segment; a first end of the capacitor network is connected with a second end of the first coil segment, and a second end of the capacitor network is connected with a first end of the second coil segment; an output end of the first differential amplifier transistor is coupled to a first end of the first coil segment, and an output end of the second differential amplifier transistor is coupled to a second end of the second coil segment. In the application, the capacitor network arranged on the push-pull power amplifier chip is connected to the connection of the first coil segment and the second coil segment of the first balun arranged on the substrate. The capacitor network and first balun jointly participate in impedance matching of the push-pull RF power amplifier circuit to improve the bandwidth performance of the push-pull power amplifier circuit, especially the bandwidth performance of the fundamental wave impedance. Moreover, since the capacitor network is arranged on the push-pull power amplifier chip, the occupied area of the push-pull RF power amplifier can be reduced, and meanwhile, the quality factor can be improved, thus optimizing the overall performance of the push-pull RF power amplifier circuit.

In one embodiment, the push-pull power amplifier chip may be a chip manufactured by processes such as GaAs or GaN.

Understandably, for the wire bonding mode adopted in the embodiments of the present application, one or more wires may be used for the connection, the details are not repeated here.

The above embodiments are merely used to illustrate the technical solution of the present application, rather than limit it. Although the application has been described in detail with reference to the foregoing embodiments, it should be understood by those skilled in the art that it is still possible to modify the technical solutions described in the foregoing embodiments, or equivalently replace some technical features thereof. These modifications and equivalents do not make the nature of the corresponding technical solution deviates from the spirit and scope of the present application, and shall be included in the protection scope of the present application.

1. A push-pull RF power amplifier circuit, comprises a first differential amplifier transistor, a second differential amplifier transistor, a first balun and a capacitor network;
a primary coil of the first balun comprises a first coil segment and a second coil segment;
a first end of the capacitor network is connected with a second end of the first coil segment, and a second end of the capacitor network is connected with a first end of the second coil segment;
an output end of the first differential amplifier transistor is coupled to a first end of the first coil segment, and an output end of the second differential amplifier transistor is coupled to a second end of the second coil segment.

2. The push-pull RF power amplifier circuit of claim 1, wherein the capacitor network comprises a first capacitor, a first end of the first capacitor is connected with the second end of the first coil segment, and a second end of the first capacitor is connected with the first end of the second coil segment.

3. The push-pull RF power amplifier circuit of claim 1, wherein the capacitor network comprises a first capacitor and a second capacitor connected in series, a first end of the first capacitor is connected with the second end of the first coil segment, a second end of the first capacitor is connected with a first end of the second capacitor, and a second end of the second capacitor is connected with the first end of the second coil segment.

4. The push-pull RF power amplifier circuit of claim 3, wherein the second end of the first capacitor is connected to ground.

5. The push-pull RF power amplifier circuit of claim 3, further comprising a common-mode rejection circuit, one end of the common-mode rejection circuit is coupled between the first capacitor and the second capacitor, and another end is grounded.

6. The push-pull RF power amplifier circuit of claim 5, wherein the common-mode rejection circuit comprises a first resistor.

7. The push-pull RF power amplifier circuit of claim 5, wherein the common-mode rejection circuit comprises a third capacitor and a first inductor connected in series.

8. The push-pull RF power amplifier circuit of claim 4, further comprising a feed power end and a decoupling capacitor, wherein the output end of the first differential amplifier transistor is connected to the feed power end via a second inductor, and the output end of the second differential amplifier transistor is connected to the feed power end via a third inductor; one end of the decoupling capacitor is connected to the feed power end, and another end is grounded.

9. The push-pull RF power amplifier circuit of claim 1, wherein the capacitor network has a capacitance value smaller than that of a DC blocking capacitor connected in series between the output end of the first differential amplifier transistor and a first end of the primary coil in a comparable push-pull RF power amplifier circuit; and/or, the capacitor network has a capacitance value smaller than that of a DC blocking capacitor connected in series between the output end of the second differential amplifier transistor and a second end of the primary coil in a comparable push-pull RF power amplifier circuit.

10. The push-pull RF power amplifier circuit of claim 1, wherein the capacitance value of the capacitor network is half of that of a DC blocking capacitor connected in series between the output end of the first differential amplifier transistor and a first end of the primary coil in a comparable push-pull RF power amplifier circuit; and/or, the capacitance value of the capacitor network is half of that of a DC blocking capacitor connected in series between the output end of the second differential amplifier transistor and a second end of the primary coil in a comparable push-pull RF power amplifier circuit.

11. The push-pull RF power amplifier circuit of claim 1, wherein the first differential amplifier transistor is a BJT and has a base, a collector and an emitter, wherein the base of the first differential amplifier transistor receives a first RF input signal, the collector of the first differential amplifier transistor is coupled to the first end of the first coil segment, and the emitter of the first differential amplifier transistor is grounded; the second differential amplifier transistor is a BJT and has a base, a collector and an emitter, wherein the base of the second differential amplifier transistor receives a second RF input signal, the collector of the second differential amplifier transistor is coupled to the second end of the second coil segment, and the emitter of the second differential amplifier transistor is grounded.

12. The push-pull RF power amplifier circuit of claim 1, wherein a first end of a secondary coil of the first balun outputs an amplified first RF output signal, and a second end of a secondary coil outputs an amplified second RF output signal; or, the first end of the secondary coil of the first balun outputs an amplified RF output signal, and the second end of the secondary coil is grounded.

13. The push-pull RF power amplifier circuit of claim 1, further comprising a first feed power end and a second feed power end, wherein the first feed power end is connected to the first end of the first coil segment, and the second feed power end is connected to the second end of the second coil segment.

14. A push-pull RF power amplifier, comprising a substrate, a push-pull power amplifier chip arranged on the substrate and a first balun arranged on the substrate; the push-pull power amplifier chip comprises a first differential amplifier transistor, a second differential amplifier transistor and a capacitor network; a primary coil of the first balun comprises a first coil segment and a second coil segment; a first end of the capacitor network is connected with a second end of the first coil segment, and a second end of the capacitor network is connected with a first end of the second coil segment;
an output end of the first differential amplifier transistor is coupled to a first end of the first coil segment, and an output end of the second differential amplifier transistor is coupled to a second end of the second coil segment.

15. The push-pull RF power amplifier of claim 14, wherein the first end of the capacitor network is connected to a first pad of the push-pull power amplifier chip, and the first pad is bonded to the second end of the first coil segment by a wire; the second end of the capacitor network is connected to a second pad of the push-pull power amplifier chip, and the second pad is bonded to the first end of the second coil segment by a wire.

16. The push-pull RF power amplifier of claim 15, wherein the capacitor network comprises a first capacitor, a first end of the first capacitor is connected to the first pad of the push-pull power amplifier chip, and the first pad is bonded to the second end of the first coil segment by a wire; a second end of the first capacitor is connected to the second pad of the push-pull power amplifier chip, and the second pad is bonded to the first end of the second coil segment by a wire.

17. The push-pull RF power amplifier of claim 15, wherein the capacitor network comprises a first capacitor and a second capacitor connected in series, the first end of the first capacitor is connected to the first pad of the push-pull power amplifier chip, and the first pad is bonded to the second end of the first coil segment by a wire; the second end of the first capacitor is connected with a first end of the second capacitor, a second end of the second capacitor is connected with the second pad of the push-pull power amplifier chip, and the second pad is bonded to the first end of the second coil segment by a wire.

18. (canceled)

19. The push-pull RF power amplifier of claim 14, wherein the output end of the first differential amplifier transistor is connected to a third pad of the push-pull power amplifier chip, and the third pad is bonded to the first end of the first coil segment by a wire; the output end of the second differential amplifier transistor is connected to a fourth pad of the push-pull power amplifier chip, and the fourth pad is bonded to the second end of the second coil segment by a wire.

20. A push-pull RF power amplifier, comprising a substrate, a push-pull power amplifier chip arranged on the substrate, and a first balun and a capacitor network arranged on the substrate; the push-pull power amplifier chip comprises a first differential amplifier transistor and a second differential amplifier transistor; a primary coil of the first balun comprises a first coil segment and a second coil segment; a first end of the capacitor network is connected with a second end of the first coil segment, and a second end of the capacitor network is connected with a first end of the second coil segment; an output end of the first differential amplifier transistor is coupled to a first end of the first coil segment, and an output end of the second differential amplifier transistor is coupled to a second end of the second coil segment.

21. (canceled)

22. (canceled)

23. (canceled)

24. (canceled)

25. (canceled)

26. (canceled)

27. An RF front-end module, comprising a push-pull RF power amplifier circuit of claim 1.
